(19) United States
(12) Patent Application Publication
(10) Pub. No.: US 2016/0172406 A1
(43) Pub. Date: Jun. 16, 2016

(54) SEMICONDUCTOR DEVICE AND SOLID-STATE IMAGING DEVICE

(71) Applicant: Kabushiki Kaisha Toshiba, Minato-ku (JP)

(72) Inventor: Mitsutaka KAWANO, Kawasaki (JP)

(73) Assignee: Kabushiki Kaisha Toshiba, Minato-ku (JP)

(21) Appl. No.: 14/958,262

(22) Filed: Dec. 3, 2015

(30) Foreign Application Priority Data
Dec. 10, 2014 (JP) 2014-249703

(51) Int. Cl. H01L 27/146

(52) U.S. Cl. CPC H01L 27/14636

(57) ABSTRACT

Certain embodiments provide a semiconductor device including a semiconductor substrate having an element portion, an insulating film provided on a main surface of the semiconductor substrate, at least one wire provided on the insulating film and electrically connected to the element portion, an uneven portion provided on the main surface side of the semiconductor substrate, and a protection film provided in contact with the wire and the uneven portion, and also in contact with the insulating film.

### CROSS REFERENCE TO RELATED APPLICATIONS

This application is based upon and claims the benefit of priority from the prior Japanese Patent Application No. 2014-249703 filed in Japan on Dec. 10, 2014; the entire contents of which are incorporated herein by reference.

### FIELD

Embodiments described herein relate generally to a semiconductor device and a solid-state imaging device.

### BACKGROUND

As an example of a wafer level chip scale package (WLCSP) type semiconductor device, a solid-state imaging device including a sensor portion having a pixel portion, an adhesive layer formed in a ring shape on the sensor portion, and a glass substrate disposed on the adhesive layer has been known. In such a WLCSP type solid-state imaging device, wires are formed on the lower surface side of the sensor portion and connected to the pixel portion via an insulating film. In addition, a solder resist film is formed in contact with the insulating film including the wires. The solder resist film is formed to cover the wires to protect the wires.

In such a conventional WLCSP type solid-state imaging device, an adhesive strength of the solder resist film against the insulating film is extremely weak compared to that against wires made of metal. If the solid-state imaging device is damaged during the manufacturing process of the solid-state imaging device or externally damaged after the manufacturing process of the solid-state imaging device, breaking, missing, cracking, etc. of the insulating film may occur. As a result, the solder resist film may be peeled off from the insulating film, causing a decrease of reliability of the solid-state imaging device.

### BRIEF DESCRIPTION OF THE DRAWINGS

FIG. 1 is a cross-sectional view of a solid-state imaging device according to a first embodiment;

FIG. 2 is a partial enlarged plan view of the lower surface of the solid-state imaging device according to the first embodiment;

FIG. 3 is used to explain the definition of a wiring forming region;

FIG. 4 is a cross-sectional view of a solid-state imaging device according to a second embodiment;

FIG. 5A is a partial enlarged plan view of the lower surface of the solid-state imaging device according to the second embodiment;

FIG. 5B is a partial enlarged plan view of the lower surface of the solid-state imaging device according to a first variation of the second embodiment;

FIG. 6 is a partial enlarged plan view of the lower surface of the solid-state imaging device according to a second variation of the second embodiment;

FIG. 7 is a cross-sectional view of a solid-state imaging device according to a third embodiment; and

FIG. 8 is a partial enlarged plan view of the lower surface of the solid-state imaging device according to the third embodiment.

### DESCRIPTION OF THE EMBODIMENTS

Certain embodiments provide a semiconductor device including a semiconductor substrate having an element portion, an insulating film provided on a main surface of the semiconductor substrate, at least one wire provided on the insulating film and electrically connected to the element portion, an uneven portion provided on the main surface side of the semiconductor substrate, and a protection film provided in contact with the wire and the uneven portion, and also in contact with the insulating film.

Certain embodiments provide a semiconductor device including a semiconductor substrate having an element portion, an insulating film provided on a main surface of the semiconductor substrate, a plurality of wires provided on the insulating film and each electrically connected to the element portion, and a protection film provided on the main surface side of the semiconductor substrate to cover only a wiring forming region. The wiring forming region is a region which is provided on the main surface side of the semiconductor substrate, which is closed by an outer periphery, and which includes all the wires in the wiring forming region. The outer periphery is formed by connecting several sides of the plurality of wires.

Certain embodiments provide a solid-state imaging device including a semiconductor substrate having a pixel portion on one main surface side of the semiconductor substrate, an insulating film provided on the other main surface of the semiconductor substrate, at least one wire provided on the insulating film and electrically connected to the pixel portion, an uneven portion provided on the other main surface side of the semiconductor substrate, and a protection film provided in contact with the wire and the uneven portion, and also in contact with the insulating film.

A semiconductor device according to embodiments is described in detail by referring to the accompanying drawings. In the description of individual embodiments below, a wafer level chip scale package (WLCSP) type solid-state imaging device will be described in detail as an example of the semiconductor device. The WLCSP type solid-state imaging device is a solid-state imaging device formed by manufacturing a plurality of solid-state imaging devices in a batch in the shape of a semiconductor wafer and ultimately cutting it into individual solid-state imaging devices. The WLCSP type solid-state imaging device will be referred to as the solid-state imaging device hereinafter.

### First Embodiment

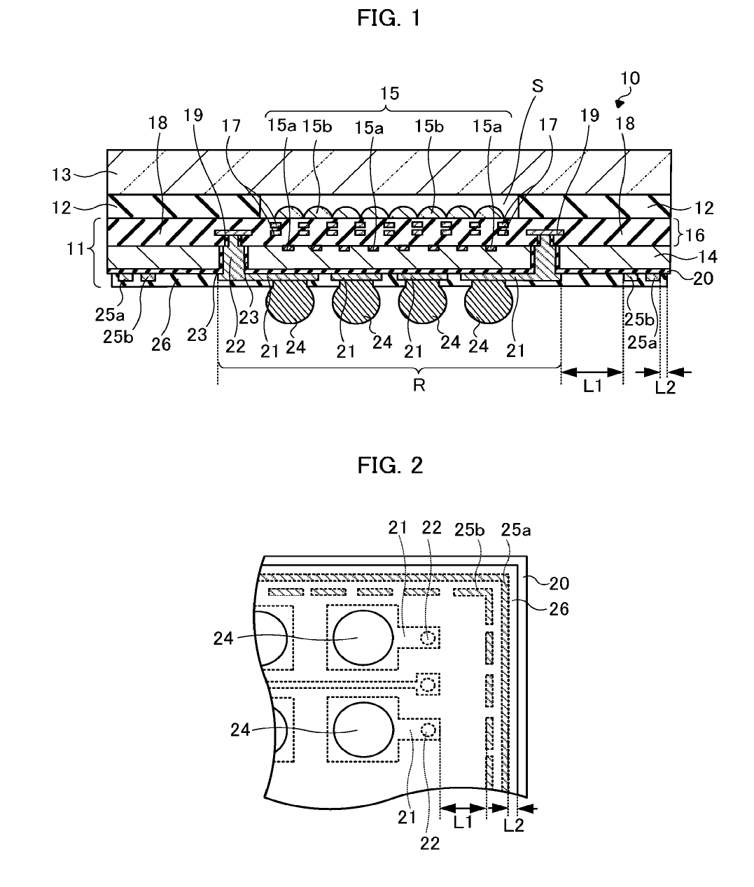

FIG. 1 is a cross-sectional view of a solid state imaging device according to a first embodiment. FIG. 2 is a partial enlarged plan view of the lower surface of the solid-state imaging device according to the first embodiment.

A solid-state imaging device 10 illustrated in FIG. 1 and FIG. 2 includes a sensor portion 11, an adhesive layer provided on the sensor portion 11, and a transparent substrate 13 provided on the sensor portion 11 via the adhesive layer 12.

The sensor portion 11 is formed by providing a pixel portion 15 as an element portion on the upper surface side which is one main surface side of the semiconductor substrate 14. The pixel portion 15 of the semiconductor substrate 14 has a plurality of light receiving portions 15a. The semiconductor substrate 14 is, for example, a silicon substrate made of silicon, and each of the plurality of light receiving portions 15a is, for example, a photo diode layer. The plurality of light receiving portions 15a is arranged two-dimensionally nearly at the center of the upper surface of the semiconductor substrate 14.

In the sensor portion 11, a wiring layer 16 is provided on the upper surface of the semiconductor substrate 14. The wiring layer 16 is a multi-layered wiring layer formed such that a plurality of internal wires 17, which are provided in multiple layers (e.g., two layers), are insulated from each other by an interlayer insulating film 18. A plurality of internal electrodes 19 is provided in the wiring layer 16 and electrically connected with the internal wires 17 of the wiring layer 16. The plurality of internal wires 17 and the plurality of internal electrodes 19 are made of metal materials, such as Al or Cu. The interlayer insulating film 18 is made of, for example, SiO₂.

The internal wires 17 of the wiring layer 16 are arranged not to cover immediately above the light receiving portions 15a, which have been formed on the upper surface of the semiconductor substrate 14, such that the internal wires 17 do not block reception of incident light.

Further, in the sensor portion 11, a plurality of micro lenses 15b is provided on the upper surface of the wiring layer 16. The plurality of light receiving portions 15a and the plurality of micro lenses 15b constitute the pixel portion 15. The plurality of micro lenses 15b is arranged in an array above the plurality of the light receiving portions 15a. The micro lenses 15b are made of, for example, a transparent resin material having a heat flow characteristic. The micro lenses 15b may also be made of a photosensitive transparent resin material.

The sensor portion 11 is thus formed and the adhesive layer 12 is provided on the upper surface of the sensor portion 11. The adhesive layer 12 is formed in a ring shape along a rectangular outer periphery of the sensor portion 11. Specifically, the adhesive layer 12 is formed in a ring shape to surround the plurality of micro lenses 15b at a predetermined region on the upper surface, including the outer periphery thereof, of the wiring layer 16 of the sensor portion 11. A distance between the upper surface of the sensor portion 11 (upper surface of the wiring layer 16) and the lower layer of the transparent substrate 13, which will be described later, is determined by the thickness of the adhesive layer 12. Therefore, the thickness of the adhesive layer 12 is at least larger than the height of the micro lenses 15b to prevent the transparent substrate 13 from touching the micro lenses 15b. Such an adhesive layer is made of, for example, an epoxy-based thermosetting resin.

The transparent substrate 13 is provided over the sensor portion 11 via the adhesive layer 12. The sensor portion 11 is fixed to the transparent substrate 13 with the adhesive layer 12. The transparent substrate 13 is a substrate used as a supporting substrate for the purpose of decreasing the thickness of the semiconductor substrate 14 of the sensor portion 11, and is made of, for example, a glass substrate.

Since the sensor portion 11 is fixed to the transparent substrate 13 with the adhesive layer 12 as described above, space S that is surrounded by the adhesive layer 12 is provided between the micro lenses 15b of the sensor portion and the transparent substrate 13.

In such a sensor portion 11 of the solid-state imaging device 10, an insulating film 20 is formed on the lower surface of the semiconductor substrate 14 (the lower surface opposite to the upper surface of the semiconductor substrate 14) , which is the other main surface of the semiconductor substrate 14. The insulating film 20 is, for example, a SiO₂ film having a thickness of about 5 μm.

A plurality of wires 21 is formed on the lower surface of the insulating film 20 on the lower surface side of the semiconductor substrate 14 of the sensor portion 11. Each of the plurality of wires 21 is a metal wire made of metal, such as Cu.

The plurality of wires 21 is electrically connected to the internal electrodes 19, which are formed in the wiring layer 16 on the upper surface of the semiconductor substrate 14, via through electrodes 22. That is, a through hole is formed under each of the internal electrodes 19 to penetrate through the semiconductor substrate 14 and the interlayer insulating film 18. An insulating film 23 extends from the insulating film 20 formed on the lower surface of the semiconductor substrate 14, and is formed on the side wall of the through hole. The through hole with the insulating film 23 is filled with metal, such as Cu, to form the through electrode 22. One end of such a through electrode 22 is in contact with the internal electrode 19 and the other end thereof is in contact with the wire 21. The plurality of wires 21 and the internal electrodes 19 in the wiring layer 16 are, therefore, electrically connected with each other via the through electrodes 22. Accordingly, the plurality of wires 21 is electrically connected to the element portion, i.e., the pixel portion 15 of the sensor portion 11 via the through electrodes 22, the internal electrodes 19, and the internal wires 17.

On the lower surface of each wire 21, an external electrode 24 is formed. The external electrode 24 is formed by, for example, a solder ball.

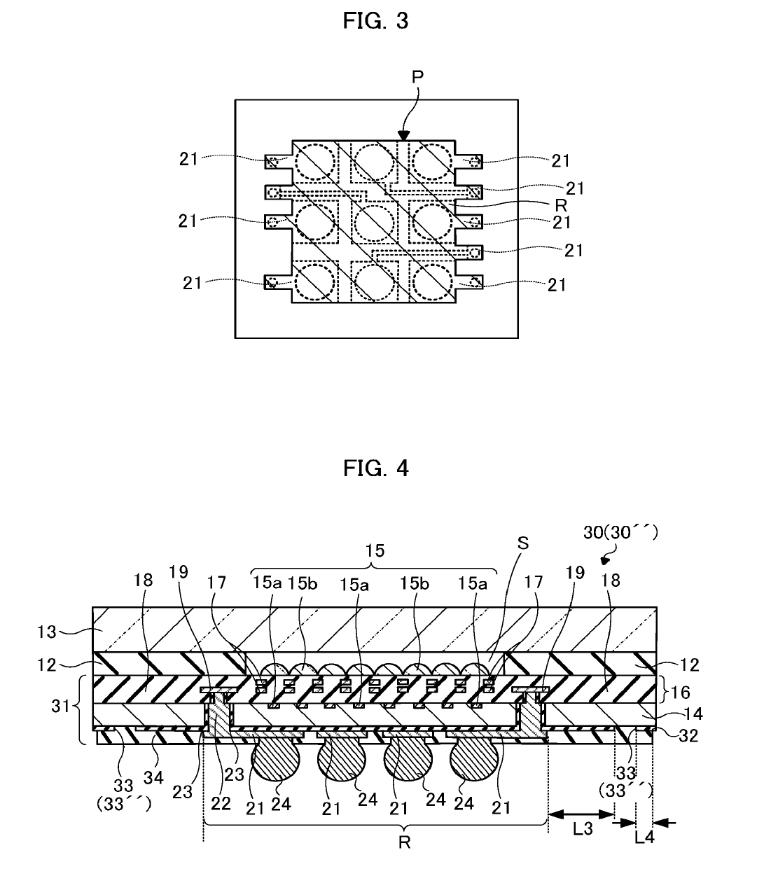

A region indicated by oblique lines in FIG. 3 is defined as a wiring forming region R. The wiring forming region R is a region which is provided on the lower surface side of the semiconductor substrate 14, which is closed by an outer periphery P, which is formed as a connecting line of several sides of the plurality of wires 21, and which includes all wires 21 in the region. All wires 21 are included in the wiring forming region R.

By referring to FIG. 1 and FIG. 2 again, a plurality of projections that constitute a plurality of uneven portions is provided around the wiring forming region R on the lower surface side of the semiconductor substrate 14.

The plurality of projections may be formed, for example, by dummy wires 25a, 25b which are floating wires substantially insulated from all wires 21. Each of the dummy wires 25a, 25b is a metal wire made of metal such as Cu, and provided in a ring shape along the outer periphery of the lower surface of the semiconductor substrate 14 on the lower surface of the insulating film 20 surrounding the wiring forming region R. In the present embodiment, two dummy wires 25a, 25b are formed at positions separated from each other. Outer dummy wire 25a is a single ring-shaped wire formed around the wiring forming region R. Inner dummy wire 25b is formed by a number of wires divided from a single ring-shaped wire. The wires forming the inner dummy wire 25b are arranged in a ring shape between the wiring forming region R and the outer dummy wire 25a. The dummy wires 25a, 25b are formed by metal wires of Cu or the like, with a line width of, for example, about 10 μm and a thickness of about 5 μm. The dummy wires 25a, 25b are positioned such that a distance L1 between the inner dummy wire 25b and the wiring forming region R is 20 μm, and a distance L2 between the outer dummy wire 25a and end faces of a protection film 26, which will be described later, is 5 μm.

It is noted that, in this application, the number of dummy wires is not fixed, and the dummy wires to be formed may be a single ring-shaped wire like the outer dummy wire 25a, or a single ring-shaped wire divided into a plurality of wires like the inner dummy wire 25b. Further, the dummy wires 25a, 25b are not necessarily made of metal. Preferably, the dummy wires 25a, 25b may be made of a material such the adhesive strength between the wires 25a, 25b and the protection film 26 can be stronger than the adhesive strength between the insulating film 32 and the protection film 26. By considering the adhesive strength, the dummy wires 25a, 25b are preferably formed by metal wires.

The protection film 26 is formed on the lower surface of the insulating film 20, on which the dummy wires 25a, 25b and the plurality of wires 21 have been formed, in such a manner that the protection film 26 is in contact with each of the plurality of wires 21 and the dummy wires 25a, 25b and also in contact with the lower surface of the insulating film 20 exposed from among the plurality of wires 21 and the dummy wires 25a, 25b. The protection film 26 is at least a film to protect the wires 21, and may be formed by a solder resist film made of resin.

The protection film 26 is arranged such that end faces thereof are positioned somewhat inside the side faces of the semiconductor substrate 14, to thereby suppress peel-off of the protection film 26 from the insulating film due to any damage applied to the side faces of the solid-state imaging device 10. When the protection film 26 has corners, which are not illustrated, such corners may be rounded to suppress the peel-off caused by the pressure applied to the side faces.

With the solid-state imaging device 10 according to the present embodiment described above, the plurality of projections formed by the dummy wires 25a, 25b is arranged on the lower surface of the semiconductor substrate 14 such that the protection film 26 is in contact with such projections. Since the contact area of the protection film 26 can be increased by the contact area of the protection film 26 and the projections, it is possible to suppress the peel-off of the protection film 26 from the insulating film 20. As a result of this, the decrease of reliability of the solid-state imaging device 10 due to the peel-off of the protection film 26 from the insulating film 20 can be suppressed.

Meanwhile, since the plurality of projections are formed by the metal dummy wires 25a, 25b, the adhesive strength of the plurality of projections with the protection film 26 can further be increased. Accordingly, the peel-off of the protection film 26 from the insulating film can further be suppressed more effectively.

The plurality of projections formed by the dummy wires 25a, 25b in the solid-state imaging device 10 according to the present embodiment are provided around the wiring forming region R on the lower surface side of the semiconductor substrate 14. By considering that the protection film 26 is usually peeled off from the outer periphery of the insulating film 20, providing the plurality of projections around the wiring forming region R can further suppress the peel-off of the protection film 26 from the insulating film 20.

### Second Embodiment

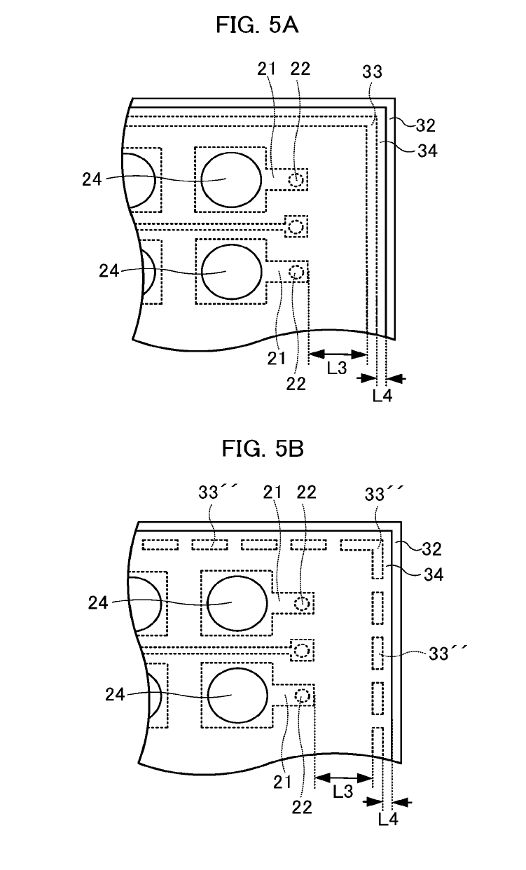

FIG. 4 is a cross-sectional view of a solid state imaging device according to a second embodiment. FIG. 5A is a partial enlarged plan view of the lower surface of the solid-state imaging device according to the second embodiment. A solid-state imaging device 30 illustrated in FIG. 4 and FIG. 5A are different from the solid-state imaging device 10 according to the first embodiment in that recesses are formed as the uneven portion on the lower surface side of the semiconductor substrate 14. In the description of the solid-state imaging device 30 according to the second embodiment below, what is different from the solid-state imaging device 10 according to the first embodiment will be described. The same reference signs are given to portions identical to those of the solid-state imaging device 10 according to the first embodiment, and the description thereof will not be repeated.

As illustrated in FIG. 4 and FIG. 5A, an insulating film 32, such as a SiO₂ film having a thickness of about 5 μm is provided on the lower surface of the semiconductor substrate 14 of the sensor portion 31. In the insulating film 32 formed around the wiring forming region R, recesses that constitute the uneven portion are provided. The recesses are formed by a ring-shaped groove 33 that surrounds the wiring forming region R and provided in the insulating film 32 along the outer periphery of the lower surface of the semiconductor substrate 14. The lower surface of the semiconductor substrate 14 is exposed from the groove 33. In the present embodiment, a single ring-shaped groove 33 is provided. The groove 33 has, for example, a thickness of about 10 μm, and a depth is set such that the groove 33 penetrates the insulating film 32. The groove 33 is provided at such a position that a distance L3 between the groove 33 and the wiring forming region R is 20 μm, and a distance L4 between the groove 33 and the end faces of the protection film 34 is 15 μm.

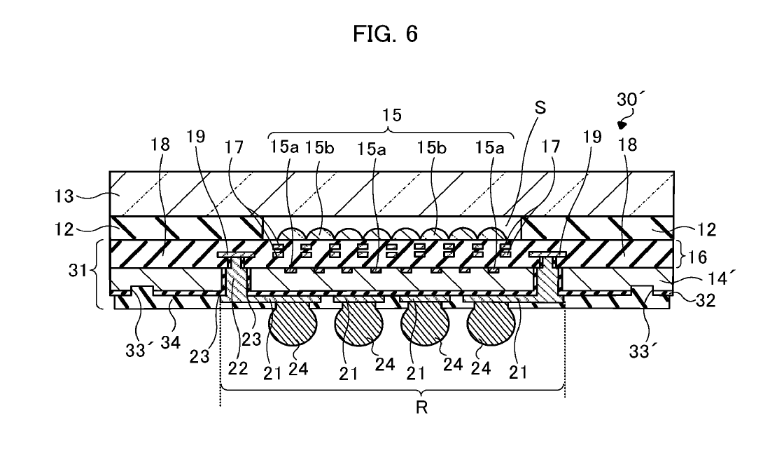

In this application, the number of groove is not fixed. The groove to be formed may be a single ring-shaped groove 33, as illustrated in FIG. 5A, or may be a number of grooves 33″ divided from a single ring, as in the solid-state imaging device 30″ illustrated in FIG. 5B. The depth of the groove is not fixed, either. A groove 33′ having such a depth that the groove 33′ penetrates the insulating film 32 to reach inside of a semiconductor substrate 14′, as illustrated in a solid-state imaging device 30′ of FIG. 6, may be provided.

On the lower surface of the insulating film 32, on which the grooves 33 (33″, 33′) and the plurality of wires 21 are provided, the protection film 34 is formed in contact with the inner wall of the plurality of wires 21 and the groove (33″, 33′) .

According to the solid-state imaging device 30 (30″, 30′) of the present embodiment, the recesses formed by the groove 33 (33″, 33′) are formed on the lower surface of the semiconductor substrate 14(14″), and the protection film 34 is formed in contact with the inner wall surface of the recesses. Since the contact area of the protection film can be increased by the contact area between the protection film 34 and the recesses, it is possible to suppress the peel-off of the protection film 34 from the insulating film 32. As a result of this, the decrease of reliability of the solid-state imaging device 30 (30″, 30′) due to the peel-off of the protection film 34 from the insulating film 32 can be suppressed.

The contact area of the protection film 34 and the recesses can further be increased by forming the recesses as the groove 33′ having a depth such that the groove 33′ penetrates the insulating film 32 to reach the inside of the semiconductor substrate 14′. Accordingly, the peel-off of the protection film 34 from the insulating film can further be suppressed more effectively.

In the solid-state imaging device 30 (30″, 30′) according to the present embodiment, the recesses formed by the groove 33 (33″, 33′) are provided around the wiring forming region R on the lower surface side of the semiconductor substrate 14 (14′). Accordingly, the peel-off of the protection film 34 from the insulating film can be suppressed more effectively due to the reason similar to that described in the first embodiment above.

### Third Embodiment

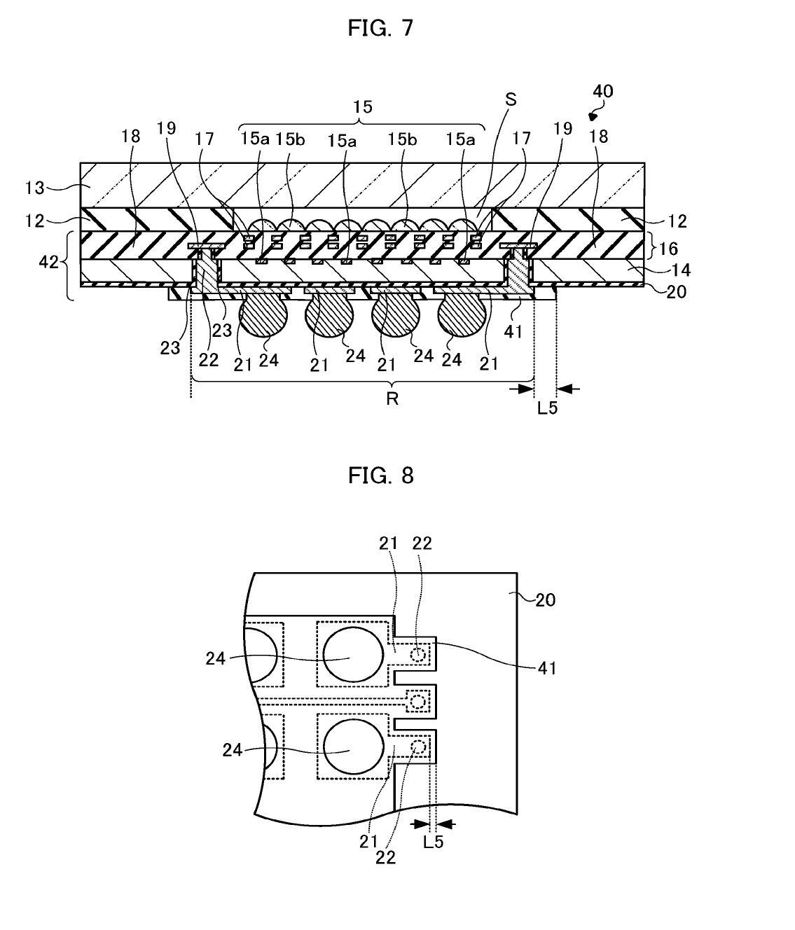

FIG. 7 is a cross-sectional view of a solid-state imaging device according to a third embodiment. FIG. 8 is a partial enlarged plan view of the lower surface of the solid-state imaging device according to the third embodiment. A solid-state imaging device 40 illustrated in FIG. 7 and FIG. 8 are different from the solid-state imaging device 10 according to the first embodiment and the solid-state imaging device 30 according to the second embodiment in that the uneven portion is not provided on the lower surface side of the semiconductor substrate 14, and a protection film 41 is formed in a different region. In the description of the solid-state imaging device 40 according to the third embodiment below, what is different from the solid-state imaging device 10 according to the first embodiment will be described. The same reference signs are given to portions identical to those of the solid-state imaging device 10 according to the first embodiment, and the description thereof will not be repeated.

As illustrated in FIG. 7 and FIG. 8, a protection film 41 of a sensor portion 42 is formed to substantially cover the wiring forming region R alone in the solid-state imaging device 40. That is, the protection film 41 is formed such that end faces thereof are located at positions outside the wiring forming region R by a predetermined distance. The predetermined distance herein refers to the minimum distance necessary for proper protection of the wires by the protection film 41, and may be set to about L5=15 μm in the present embodiment.

In the solid-state imaging device 40 according to the present embodiment described above, the peel-off of the protection film 41 due to the damage of the side faces of the solid-state imaging device 40 can be suppressed, as such damage does not reach to the protection film 41. As a result of this, the decrease of reliability of the solid-state imaging device 40 due to the peel-off of the protection film from the insulating film 20 can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the embodiments described above, the solid-state imaging devices 10, 30, 30″, 30′, and 40, in which the pixel portion 15 is provided as the element portion, have been described as examples of the semiconductor device. However, the present invention can also be applied to other semiconductor elements, such as a field effect transistor, or semiconductor devices including a circuit that use such a semiconductor element in the element portion.

Further, in the embodiments described above, the solid-state imaging devices 10, 30, 30″, 30′, and 40, in which the pixel portion 15 is provided as the element portion on one main surface side of the semiconductor substrate 14, 14′, and the uneven portions is provided on the other main surface side of the semiconductor substrate 14, 14′, have been described as examples. However, the present invention can also be applied to a semiconductor device in which the element portion is provided on one main surface side of the semiconductor substrate, and the uneven portion is also provided on the one main surface of the semiconductor substrate around the element portion.

What is claimed is:

1. A semiconductor device, comprising:
a semiconductor substrate having an element portion;
an insulating film provided on a main surface of the semiconductor substrate;
at least one wire provided on the insulating film and electrically connected to the element portion;
an uneven portion provided on the main surface side of the semiconductor substrate; and
a protection film provided in contact with the wire and the uneven portion, and also in contact with the insulating film.

2. The semiconductor device according to claim 1, wherein the uneven portion is a projection provided on the insulating film.

3. The semiconductor device according to claim 2, wherein the projection is a dummy wire formed by a metal wire.

4. The semiconductor device according to claim 3, wherein
the at least one wire comprises a plurality of wires,
the semiconductor device further comprises a wiring forming region which is provided on the main surface side of the semiconductor substrate, which is closed by an outer periphery, and which includes all the wires in the wiring forming region, the outer periphery being formed by connecting several sides of the plurality of wires, and
the dummy wire is provided around the wiring forming region.

5. The semiconductor device according to claim 4, wherein the dummy wire is shaped like a ring along the outer periphery of the main surface of the semiconductor substrate.

6. The semiconductor device according to claim 4, wherein the dummy wire is shaped like a divided ring.

7. The semiconductor device according to claim 1, wherein the uneven portion is formed by a groove provided in the insulating film.

8. The semiconductor device according to claim 7, wherein
the at least one wire comprises a plurality of wires,
the semiconductor device further comprises a wiring forming region which is provided on the main surface side of the semiconductor substrate, which is closed by an outer periphery, and which includes all the wires in the wiring forming region, the outer periphery being formed by connecting several sides of the plurality of wires, and
the groove is provided around the wiring forming region.

9. The semiconductor device according to claim 8, wherein the groove is shaped like a ring along the outer periphery of the main surface of the semiconductor substrate.

10. The semiconductor device according to claim 8, wherein the groove is shaped like a divided ring.

11. The semiconductor device according to claim 8, wherein the groove penetrates the insulating film.

12. The semiconductor device according to claim 8, wherein the groove is provided so as to penetrate the insulating film and reach the inside of the semiconductor substrate.

13. A semiconductor device, comprising:
a semiconductor substrate having an element portion;
an insulating film provided on a main surface of the semiconductor substrate;
a plurality of wires provided on the insulating film and each electrically connected to the element portion; and
a protection film provided to cover only a wiring forming region, the wiring forming region being provided on the main surface side of the semiconductor substrate, being closed by an outer periphery which is formed by connecting several sides of the plurality of wires, and including all the wires in the wiring forming region.

14. A solid-state imaging device, comprising:
a semiconductor substrate having a pixel portion, the pixel portion being provided on one main surface side of the semiconductor substrate;
an insulating film provided on the other main surface of the semiconductor substrate;
at least one wire provided on the insulating film and electrically connected to the element portion;
an uneven portion provided on the other main surface side of the semiconductor substrate; and
a protection film provided in contact with the wire and the uneven portion, and also in contact with the insulating film.
